(19) United States
(12) Patent Application Publication
(10) Pub. No.: US 2011/0012762 A1
(43) Pub. Date: Jan. 20, 2011

(54) METHOD AND DEVICE FOR DIGITIZING AN ANALOG ELECTRICAL SIGNAL AND METHOD FOR DIGITIZING

(75) Inventors: Thomas Driehorn, Berlin (DE); Harald Günther, Feucht (DE); Jürgen Haible, Numberg (DE)

Correspondence Address: HARNESS, DICKEY & PIERCE, P.L.C., P.O.BOX 8910, RESTON, VA, 20195, US

(73) Assignee: SIEMENS AKTIENGESELLSCHAFT, Munich (DE)

(21) Appl. No.: 12/835,803

(22) Filed: Jul. 14, 2010

(30) Foreign Application Priority Data
Jul. 16, 2009 (DE) 10 2009 033 983.3

(51) Int. Cl. H03M 1/06; H03M 1/18

(52) U.S. Cl. 341/118; 341/139

(57) ABSTRACT

A method and a device are disclosed for digitizing an analog electrical signal, in which the signal is applied to a number of subchannels connected in parallel. In at least one embodiment, the amplitude ranges of immediately adjacent subchannels with respect to amplitude are in each case displaced overlapping one another, in which the overlapping amplitude ranges include the total amplitude range, in which a subchannel serves as reference channel, in which, on the basis of the reference channel, the digital output value of the immediately adjacent subchannel with respect to amplitude is corrected when the signal is in the overlap range of the two subchannels and the digital values differ from one another, and in which a total digital value is output by way of a digital output value, taking into consideration the displacements of the amplitude ranges with respect to one another.

### PRIORITY STATEMENT

The present application hereby claims priority under 35 U.S.C. §119 on German patent application number DE 10 2009 033 983.3 filed Jul. 16, 2009, the entire contents of which are hereby incorporated herein by reference.

### FIELD

At least one embodiment of the invention generally relates to a method and/or to a device for digitizing an analog electrical signal.

### BACKGROUND

Devices (and the associated methods) for digitizing, in particular, analog electrical voltages are generally known as A/D converters. Problems arise when the digitization is to take place over a very large dynamic range of, for example, 22 bits or more. Thus, circuit breakers require alternating currents to be detected within a range of from 20 A to 800 000 A. Given an accuracy of 1%, this requires a resolution of 200 mA with a 20-A signal but of 20 A in the case of 2000 A. Overall, this example results in a dynamic range of 800 000/0.2=4 000 000 corresponding to 132 dB or 22 bits. In this context, A/D converters having a “real” 22-bit accuracy with required sampling rates of 8 kHz are technically not yet feasible and will initially be very expensive, should they become available.

Furthermore, programmable gain amplifiers (PGA) are also known which amplify the signal to be digitized to a greater or lesser degree in dependence on the respective signal amplitude so that the subsequent A/D converter is in each case optimally driven in order to thus achieve an adequate accuracy. The disadvantageous factor is in this context, however, that the programmable gain amplifiers must have high precision which is relatively expensive. If several amplifier stages are used, they must also be calibrated very accurately. In this context, the individual amplifier stages may have to be switched very rapidly in each case in order to avoid temporary over- or underdriving of the A/D converter.

Logarithmic amplifiers are also known which, however, would initially have to be constructed in expensive analog technology. Recalculation in a downstream digital part would be complex and any required temperature compensation would be difficult.

### SUMMARY

In at least one embodiment of the invention, at least one of a device and/or an associated method are proposed for digitizing signals having a very large dynamic range.

With respect to the method, the solution proposes that the signal is applied to a number of subchannels connected in parallel which output at their output end a digital value of the signal, that the amplitude ranges of the subchannels are in each case smaller than the total amplitude range, that the amplitude ranges of immediately adjacent subchannels with respect to amplitude are in each case displaced overlapping one another, that the overlapping amplitude ranges comprise the predetermined total amplitude range, that a subchannel serves as reference channel, that, on the basis of the reference channel, the digital output value of the immediately adjacent subchannel with respect to amplitude is corrected when the signal is in the overlap range of the two subchannels and the digital values differ from one another and that a total digital value is output by means of a digital output value, taking into consideration the displacements of the amplitude ranges with respect to one another. Roughly speaking, the concept of the invention thus consists in connecting a number of overlapping subchannels in parallel, preventing a drifting apart of the subchannels by correcting the corresponding digital values and subsequently recombining the digital values of the subchannels intelligently. Intelligent means: only the appropriate ones of the digital values supplied by the subchannels are used. During the combining, the displacements of the amplitude ranges with respect to one another are correspondingly taken into consideration. For the correction, the digital values of two immediately adjacent subchannels are always used. Thus, the subchannels always correct themselves mutually, with the exception of the reference channel which is the only one to be corresponding calibrated.

A simplified consideration of the displacement in the determination of the total digital value provides that the amplitude ranges of the subchannels in the total amplitude range form a staggered arrangement.

To be able to adjust the drive during the digitization in a simple manner, it is proposed that the subchannels have at their input end in each case an analog signal amplification.

To achieve a technically simple embodiment, powers of two are in each case chosen for the signal amplifications of the subchannels.

In a simple embodiment, the subchannels are in each case provided with the same A/D converters for the digitization.

The evaluation is simplified if the displacements of the staggered amplitude ranges of the subchannels in each case have the same number of bits with respect to one other.

It requires little mathematical expenditure if the displacements of the staggered amplitude ranges of the subchannels with respect to one another are simply taken into consideration for determining the total digital value by way of the number of bits corresponding to the displacements.

A simple correction of the signal amplifications is obtained if the displacements are taken into consideration by multiplication by a multiplier in each case allocated to the subchannel.

With reference to the device, the solution provides that a number of subchannels are connected in parallel and the subchannels in each case output a digital value of the analog signal, the amplitude ranges of which in each case being smaller than the total amplitude range of the device, the amplitude ranges of immediately adjacent subchannels with respect to amplitude being displaced with respect to one another in such a manner that they overlap, the overlapping amplitude ranges comprising the predetermined total amplitude range and a subchannel serving as reference channel. Furthermore, a correction is provided which in each case corrects on the basis of the reference channel the digital output value of the immediately adjacent subchannel with respect to amplitude when the signal is in the overlap range of the two subchannels and the digital values differ from one another. Furthermore, the device has a transfer arrangement which forms a total digital value by means of the digital output values of the subchannels, taking into consideration the displacements of the amplitude ranges with respect to one another.

### BRIEF DESCRIPTION OF THE DRAWINGS

In the text which follows, the invention will be described in greater detail by way of an example embodiment, in which:

FIG. 1 shows a block diagram of a device for digitizing an analog electrical signal, comprising three subchannels connected in parallel,

FIG. 2 shows the position of the amplitude ranges of the subchannels with respect to the total amplitude range D of the device according to FIG. 1,

FIG. 3 shows a block diagram of a device with compensation of the analog signal amplifications after the A/D converters, and

FIG. 4 shows the transfer of the digital values of the subchannels from a common digital signal processing arrangement.

### DETAILED DESCRIPTION OF THE EXAMPLE EMBODIMENTS

Various example embodiments will now be described more fully with reference to the accompanying drawings in which only some example embodiments are shown. Specific structural and functional details disclosed herein are merely representative for purposes of describing example embodiments. The present invention, however, may be embodied in many alternate forms and should not be construed as limited to only the example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

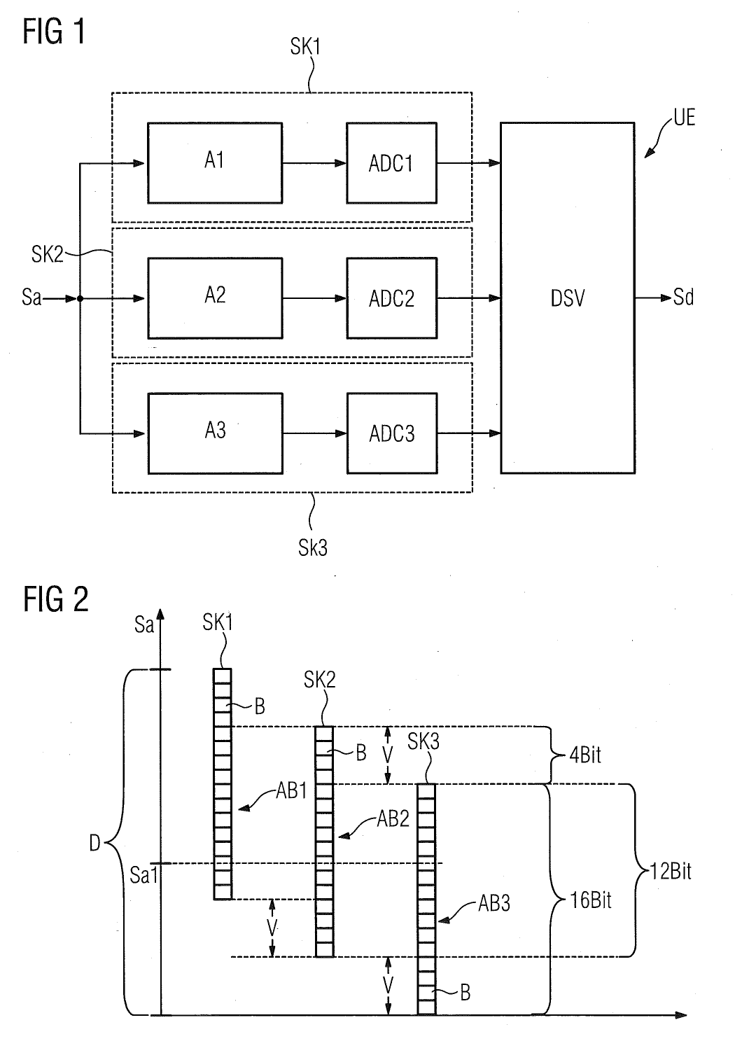

FIG. 1 shows a block diagram of a device for digitizing an analog electrical signal Sa. The device has a number of (in this case three) subchannels SK1, SK2, SK3 connected in parallel, at which the signal Sa is simultaneously present. The signal Sa is subsequently amplified in each subchannel SK1, SK2, SK3 (signal amplification A1, A2, A3) before it is applied to the input of an A/D converter ADC1, ADC2, ADC3. The output values of the A/D converters ADC1, ADC2, ADC3 subsequently reach a common digital signal processing arrangement DSV which accepts the values (transfer UE) and forms from these and outputs a total digital value Sd.

The A/D converters ADC1, ADC2, ADC3 are in each case equal in the example embodiment here (but different A/D converters can also be used in each subchannel SK1, SK2, SK3).

The amplitude of the signal Sa is within a total amplitude range (total dynamic range) D of 24 bits. The required accuracy of the device is 12 bits with a resolution of the A/D converter ADC of 16 bits. The signal amplifications A1, A2, A3 are adjusted in such a manner and the A/D converters ADC1, ADC2, ADC3 are selected in such a manner that a signal Sa fully utilizing the amplitude range of 24 bits fully drives the A/D converter ADC1. (The signal amplification A1 can be, e.g. 1 or the signal amplification A1 can be omitted in this case). The signal amplification A2 of the subchannel SK2 is greater by a factor of 2⁴ than the signal amplification A1. Correspondingly, the A/D converter ADC2 is fully saturated with very large signals Sa whilst the A/D converter ADC1 still indicates these signals Sa. If the signal Sa is so small that fewer than 12 bits are used by the A/D converter ADC1, the A/D converter ADC2 (subchannel SK2) comes into play. Its input signal is the signal Sa amplified by a factor of 2⁴ which corresponds to a 4-bit offset between the A/D converters ADC1 and ADC2. If the signal Sa is so small that the A/D converter ADC2 also uses fewer than 12 bits, the A/D converter ADC3 (subchannel SK3) comes into play. Its signal amplification A3 is 2⁸ which corresponds to an offset between the A/D converters ADC2 and ADC3 of 4 bits (and correspondingly of 8 bits between the A/D converters ADC1 and ADC3).

FIG. 2 diagrammatically shows the position of the amplitude ranges AB1, AB2, AB3 with respect to the total amplitude range D of the device. The bits of the amplitude ranges AB1, AB2, AB3 are shown as boxes B in FIG. 2. Corresponding to what has been said above, each amplitude range AB1, AB2, AB3 has precisely 16 boxes B. Each amplitude range AB1, AB2, AB3 is smaller than the total amplitude range D and the amplitude ranges AB1, AB2, AB3 overlap one another, each amplitude range AB1, AB2, AB3 being displaced in each case by 4 bits with respect to the immediately adjacent amplitude range AB2 or AB3, respectively. The amplitude ranges AB1, AB2, AB3 of the subchannels SK1, SK2, SK3 thus form a staggered arrangement within the total amplitude range D, the displacement V (step-down) of which is in each case 4 bits. This ensures an accuracy of the device (system accuracy) of 12 bits with three A/D converters ADC1, ADC2, ADC3.

The signal processor DSV decides which digital value (data word) output by the three A/D converters ADC1, ADC2, ADC3 is transferred in order to output it, taking into consideration the respective displacements V in 24-bit format.

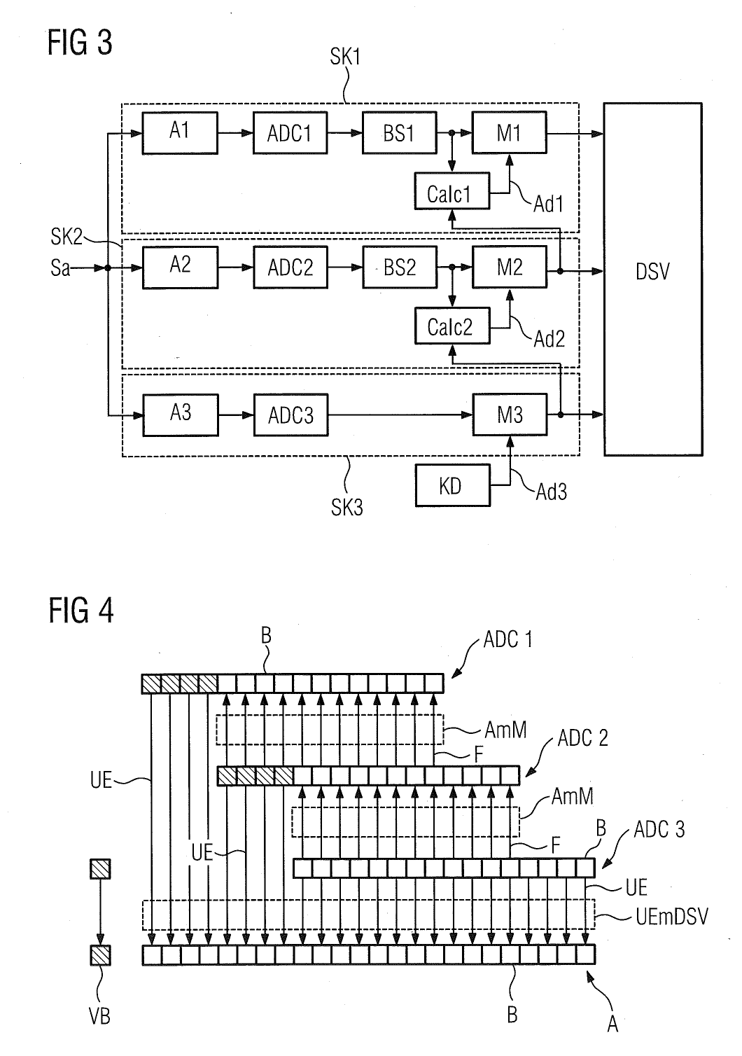

The diagrammatic representation in FIG. 3 shows a modified device, also comprising three subchannels SK1, SK2, SK3. As in FIG. 1, a signal Sa is applied to the three subchannels SK1, SK2, SK3 connected in parallel, the outputs of which are again applied to a common digital signal processor DSV for combining the digital values of the three subchannels SK1, SK2, SK3.

In the device in FIG. 3, the analog signal amplification A1, A2, A3 after the A/D converter ADC1, ADC2, ADC3 is canceled again, however, before they are combined in the signal processor DSV, so that a digital value is present again at the output of each subchannel SK1, SK2, SK3 but the digital values exhibit the same weighting here. Since the analog signal amplifications A1, A2, A3 are again powers of two (2⁴ and 2⁸, resp.), they can be compensated for by a bit shift BS1, BS2 of in each case 4 bits after the A/D converter ADC1, ADC2, ADC3.

In practice, the analog signal amplifications A1, A2, A3 always deviate slightly from the powers of two. For this reason, the bit shift BS1 and BS2, respectively, is followed by digital multipliers M1, M2, M3 which calibrate or correct the amplification of the respective subchannel SK1, SK2, SK3 via the parameters “adjust” Ad1, AD2, Ad3 (correction factors). However a subchannel, in this case the most sensitive subchannel SK3, receives its correction value KD through a (pre-)calibration (e.g. a manufacturer's calibration). The subchannel SK3 thus forms the reference channel for the other two subchannels SK1 and SK2. According to FIG. 3, the device thus has a correction based on a reference channel, in this case subchannel SK3. The parameter Ad3 in this case only corrects the signal amplification A3.

As is also shown in FIG. 3, the A/D converters ADC1, ADC2, ADC3 output the same value—in the context of their respective resolution (resolution accuracy, measuring accuracy) if the signal Sa is in the amplitude ranges AB1 and AB2 or AB2 and AB3, respectively, in which they overlap. Thus, the signal value Sa1 (see FIG. 2) is output by the two subchannels SK2 and SK3 within the context of their resolution and both digital values are compared with one another via a comparator Calc2. If the result of subchannel SK2 deviates from that of subchannel SK3, the comparison unit Calc2 correspondingly adjusts the parameter Ad2; in this manner, the subchannel SK2 is recalibrated. Subchannel SK1 is analogously readjusted via Calc1 in the case of a correspondingly large signal Sa. The correction of the subchannels SK1, SK2, which prevents a drifting apart of the three subchannels SK1, SK2, SK3 in the context of the resolution, is thus effected on the basis of the reference subchannel SK3 in each case successively via the immediately adjacent subchannels SK1 and SK2 with respect to amplitude.

The transfer of the digital values of subchannels SK1, SK2, SK3 from the digital signal processor DSV is shown diagrammatically in FIG. 4 in which the digital values are represented as an amount with separate sign bit VB (so-called sign format). Each A/D converter ADC1, ADC2, ADC3 has a 16-bit resolution which is represented in each case by 16 small boxes B in FIG. 4. The arrows F diagrammatically represent the direction of correction and the elongated boxes AmM diagrammatically represent the calibration (calibration range) by means of the multipliers M1, M2, M3. The arrows are intended to represent the transfer arrangement UE by means of the digital signal processor DSV (UEmDSV) diagrammatically. The transfer UE (the combining) of the individual digital values to form a single total digital value A (of 24 bits) can be understood more easily by means of FIG. 4, in which the digital values are represented above one another, taking into consideration the 4-bit displacement V of the amplitude ranges AB1, AB2, AB3 with respect to one another.

In the ideal case, the digital values could even be accepted simply from top to bottom by the digital signal processor DSV and output as required.

However, the digital signal processor DSV must decide in this respect (recognize) whether an A/D converter ADC1 or ADC2 or ADC3 is overdriven and which one of two valid digital values is to be accepted on the basis of the different accuracy.

Assuming initially a small signal Sa in the case of which the A/D converter ADC3 is not overdriven, all bits can be accepted by the digital signal processor DSV at the bottom into the total digital value A. At the same time, the deviation of the A/D converters ADC1 and ADC2 from the “nominal value” of the A/D converter ADC3 can be calculated (e.g. by forming the quotient) by means of each digital value. The parameters Ad1 and Ad2 are thus available for the multipliers M1 and M2. The change in parameters Ad1 and Ad2 forces the subchannels SK1 and SK2 also to indicate this digital value. If the A/D converter ADC3 is overdriven, the last correction value AD1 and AD2 is in each case retained and subchannel SK2 is the “reference” for the subchannel SK1 until further notice. The digital value of the A/D converter ADC3 is in this case ignored completely and, instead, the digital value of the A/D converter ADC2 is accepted into the result, the total digital value A. The least significant bits in the digital value, which only the A/D converter ADC3 would have been able to supply, are below the required accuracy of the device and can be optionally set to 0 (or alternatively also to 1). In this case, the subchannel SK1 is corrected (readjusted) by means of the digital value of the A/D converter ADC2. If the signal Sa is even larger so that the A/D converter ADC2 is overdriven, the digital value is transferred completely from the subchannel SK1 into the result.

If the signal Sa is smaller again, which is easily detectable by the more significant one of the left-hand upper bits in FIG. 4 becoming zero, the more sensitive subchannel SK2 or SK3, respectively, is initially added again by the digital signal processor DSV. In this process, there is no further correction via the multipliers M1, M2, M3; the last valid correction value is retained.

In the case of signals Sa in the form of direct voltages etc., the more insensitive subchannels SK1 (and SK2) have to be made the master for the multiplicative calibration of the more sensitive subchannels SK2 and SK3, if necessary, because of the drift when switching back to the more sensitive subchannels SK2 and SK3. This applies especially when they have been active for a relatively long time.

If the signal Sa is an alternating signal (e.g. an alternating voltage), the system switches from the more insensitive subchannels SK1, SK2 back to the (most sensitive) reference channel (subchannel SK3) after 10 milliseconds (after one half wave-detected by changes in the sign bit VB in FIG. 4) at the latest, in the case of 50 Hz so that a permanent calibration of the subchannels SK1, SK2, SK3 between one another takes place. This purely multiplicative calibration of the individual subchannels SK1, SK2, SK3 presupposes an offset freedom which, however, can be achieved relatively easily by way of a digital high-pass filter before the respective multiplier M1, M2, M3.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combineable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, computer readable medium and computer program product. For example, of the aforementioned methods may be embodied in the form of a system or device, including, but not limited to, any of the structure for performing the methodology illustrated in the drawings.

Even further, any of the aforementioned methods may be embodied in the form of a program. The program may be stored on a computer readable medium and is adapted to perform any one of the aforementioned methods when run on a computer device (a device including a processor). Thus, the storage medium or computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. Examples of the built-in medium include, but are not limited to, rewriteable non-volatile memories, such as ROMs and flash memories, and hard disks. Examples of the removable medium include, but are not limited to, optical storage media such as CD-ROMs and DVDs; magneto-optical storage media, such as MOs; magnetism storage media, including but not limited to floppy disks (trademark), cassette tapes, and removable hard disks; media with a built-in rewriteable non-volatile memory, including but not limited to memory cards; and media with a built-in ROM, including but not limited to ROM cassettes; etc. Furthermore, various information regarding stored images, for example, property information, may be stored in any other form, or it may be provided in other ways.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A method for digitizing an analog electrical signal, an amplitude of the electrical signal being within a total amplitude range, the method comprising:
applying the analog electrical signal to a number of subchannels connected in parallel which output, at an output end, a digital value of the signal, amplitude ranges of the subchannels each being smaller than the total amplitude range, the amplitude ranges of immediately adjacent-subchannels with respect to amplitude each being displaced overlapping one another, the overlapping amplitude ranges including the total amplitude range, and a subchannel serving as reference channel;
correcting, on the basis of the reference channel and when the electrical signal is in the overlapping amplitude range of the two subchannels and the digital values differ from one another, a digital output value of an immediately adjacent subchannel with respect to amplitude; and
outputting a total digital value by way of a digital output value, taking into consideration the displacements of the amplitude ranges with respect to one another.

2. The method as claimed in claim 1, wherein the amplitude ranges of the subchannels the total amplitude range form a staggered arrangement.

3. The method as claimed in claim 1, wherein the subchannels each have, at their respective input ends, an analog signal amplification.

4. The method as claimed in claim 3, wherein the signal amplifications of the subchannels are each powers of two.

5. The method as claimed in claim 1, wherein the subchannels include identical A/D converters for the digitization.

6. The method as claimed in claim 1, wherein the displacements of the staggered amplitude ranges of the subchannels include a same number of bits with respect to one another.

7. The method as claimed in claim 2, wherein the displacements of the staggered amplitude ranges of the subchannels with respect to one another are taken into consideration for determining the total digital value by way of a number of bits corresponding to the displacements.

8. The method as claimed in claim 1, wherein, for each of the subchannels, the displacements are taken into consideration by multiplication by a multiplier allocated to the subchannel.

9. A device for digitizing an analog electrical signal, an amplitude of the electrical signal being within a total amplitude range, comprising:
a number of subchannels connected in parallel which each output a digital value of the analog signal, amplitude ranges of the subchannels each being smaller than the total amplitude range of the device, the amplitude ranges of immediately adjacent subchannels with respect to amplitude being displaced with respect to one another in such a manner to overlap, the overlapping amplitude ranges including the total amplitude range, and a subchannel serving as reference channel;
a correction to correct, in each case and on the basis of the reference channel, the digital output value of the immediately adjacent subchannel with respect to amplitude when the electrical signal is in the overlap range of the two subchannels and the digital values differ from one another; and
a transfer arrangement to form a total digital value by way of the digital output values of the subchannels, taking into consideration the displacements of the amplitude ranges with respect to one another.

10. The method as claimed in claim 2, wherein the subchannels each have, at their respective input ends, an analog signal amplification.

11. The method as claimed in claim 10, wherein the signal amplifications of the subchannels are each powers of two.

12. A computer readable medium including program segments for, when executed on a computer device, causing the computer device to implement the method of claim 1.
